(19) United States
(12) Patent Application Publication
(10) Pub. No.: US 2025/0274715 A1
(43) Pub. Date: Aug. 28, 2025

(54) SPEAKER APPARATUS

(71) Applicant: SAMSUNG ELECTRONICS CO.,LTD., Suwon-si (KR)

(72) Inventor: Euihan YOON, Suwon-si (KR)

(73) Assignee: SAMSUNG ELECTRONICS CO.,LTD., Suwon-si (KR)

(21) Appl. No.: 19/209,367

(22) Filed: May 15, 2025

Related U.S. Application Data
(63) Continuation of application No. PCT/KR2023/016459, filed on Oct. 23, 2023.

(30) Foreign Application Priority Data
Dec. 22, 2022 (KR) 10-2022-0182351

(51) Int. Cl. H04R 9/02; H04R 1/28; H04R 9/06; H05K 7/20

(52) U.S. Cl. CPC H04R 9/022; H04R 1/2873; H04R 1/2888; H04R 9/06; H05K 7/20145; H05K 7/20154; H05K 7/20409

(57) ABSTRACT

A speaker apparatus includes a speaker, a main body on which the speaker is mounted, the main body including an outer wall extending in a first direction and having an opening, and an inner wall spaced apart from the rear wall and forming a flow path communicating with the opening, an electronic component arranged inside the main body, and a heat sink in contact with the electronic component and including a plurality of heat exchange fins protruding toward the flow path, wherein the plurality of heat exchange fins may be arranged to be spaced apart from each other in the first direction parallel to a flow direction of the air and in a second direction intersecting the first direction to allow the air passing through the flow path to contact the plurality of heat exchange fins.

### CROSS-REFERENCE TO RELATED APPLICATION

This application is continuation of International Application No. PCT/KR2023/016459, filed on Oct. 23, 2023, which based on and claims priority to Korean Patent Application No. 10-022-0182351, filed on Dec. 22, 2022, in the Korean Intellectual Property Office, the disclosures of which are incorporated by reference herein in their entireties

### BACKGROUND

### 1. Field

The disclosure relates to a speaker apparatus

### 2. Description of Related Art

A speaker generates sound by converting electrical signals into vibrations of a vibrating member.

A speaker may include a moving system, a suspension system, and a magnet system. The moving system may include components that are directly involved in sound reproduction, such as a diaphragm and a voice coil. The suspension system may include components, such as a damper and an edge, that support the outer and inner parts of the diaphragm in the correct position. The magnet system may refer to a system to optimize the movement of the diaphragm by allowing the magnetic field from the permanent magnets and the magnetic fields created by the voice coil to interact more efficiently.

Speakers may be categorized according to their shape as cone speakers, dome speakers, flat-panel speakers, ribbon speakers, horn speakers, and micro speakers. Recently, speaker devices in which a plurality of speakers are arranged in a single body are widely used.

### SUMMARY

Provided is a speaker apparatus having a structure which may have improved heat dissipation.

Further, provided is a speaker apparatus having a structure that may efficiently filter standing waves generated by an internal flow path.

Additional aspects will be set forth in part in the description which follows and, in part, will be apparent from the description, or may be learned by practice of the presented embodiments.

According to an aspect of the disclosure, a speaker apparatus includes: a main body including an outer wall having an opening configured to discharge air inside the main body to an outside of the main body, the outer wall including a rear wall extending in a first direction, and an inner wall spaced apart from the rear wall and defining a flow path in communication with the opening; a speaker on the main body; an electronic component inside the main body; and a heat sink in contact with the electronic component and including heat exchange fins protruding toward the flow path; wherein the plurality of heat exchange fins are spaced apart from each other in the first direction parallel to a flow direction of the air and in a second direction intersecting the first direction such that the air passing through the flow path contacts the plurality of heat exchange fins.

The inner wall extends in the first direction, and the heat sink is on the inner wall so as to extend in the first direction.

The heat sink penetrates the inner wall.

The heat sink further includes a connection plate connected to the plurality of heat exchange fins and attached to the electronic component, and the plurality of heat exchange fins extend from the connection plate toward the rear wall.

The inner wall includes a plate hole, and the connection plate is inserted into the plate hole and contacts the electronic component.

The electronic component is on a front side of the inner wall, and the flow path is at a rear side of the inner wall.

The plurality of heat exchange fins includes: a first heat exchange fin; a second heat exchange fin spaced apart from the first heat exchange fin in the second direction and forming an inlet through which the air passes with the first heat exchange fin; a third heat exchange fin spaced apart from the first heat exchange fin in the first direction; and a fourth heat exchange fin spaced apart from the second heat exchange fin in the first direction and forming an outlet through which the air passes with the third heat exchange fin.

The second direction is perpendicular to the first direction.

The opening is in a side surface of the outer wall of the main body.

A distance between the inner wall and the rear wall increases toward the opening such that the flow path widens toward the opening.

The inner wall includes a first end forming the opening and a second end on an opposite side of the opening, and the main body further includes a guide wall extending from the rear wall and spaced apart from the second end of the inner wall so as to surround the second end of the inner wall.

The guide wall includes: a first end connected to the rear wall, and a second end spaced apart from the inner wall to define a guide hole through which air inside the main body flows in.

The guide wall further includes a rounded portion configured to guide the air flowing in through the guide hole to the flow path behind the inner wall.

The inner wall includes a guide portion rounded toward the guide wall and configured to guide the air flowing in through the guide hole to the flow path on the rear side of the inner wall.

According to an aspect of the disclosure speaker apparatus includes: a main body including an outer wall having an opening configured to discharge air inside the main body to an outside of the main body, the outer wall including a rear wall extending in in a first direction, and an inner wall spaced apart from the outer wall and defining a flow path in communication with the opening; a speaker on the main body; an electronic component disposed on a front side of the inner wall; and a heat sink including a connection plate in contact with the electronic component and inserted into the inner wall, and a plurality of heat exchange fins protruding from the connection plate toward the flow path on a rear side of the inner wall.

The plurality of heat exchange fins are spaced apart from each other in the first direction parallel to a flow direction of the air and in a second direction perpendicular to the first direction such that the air passing through the flow path contacts the plurality of heat exchange fins.

The plurality of heat exchange fins include: a first heat exchange fin; a second heat exchange fin spaced apart from the first heat exchange fin in the second direction and forming an inlet into which the air flows with the first heat exchange fin; a third heat exchange fin spaced apart from the first heat exchange fin in the first direction; and a fourth heat exchange fin spaced apart from the second heat exchange fin in the first direction and forming an outlet through which the air passes with the third heat exchange fin.

The heat sink is inside the main body.

According to an aspect of the disclosure speaker apparatus includes: a main body extending in a first direction, the main body including an opening configured to discharge air inside the main body to an outside of the main body; a speaker on the main body; an electronic component inside the main body, and a heat sink attached to the electronic component and including a plurality of heat exchange fins, wherein the main body includes an outer wall including a rear wall extending in the first direction, and an inner wall defining a flow path in communication with the opening and extending spaced apart from the rear wall, the heat sink is on the inner wall such that the plurality of heat exchange fins protrudes toward the rear wall, and the plurality of heat exchange fins are spaced apart from each other in the first direction and in a second direction perpendicular to the first direction.

According to various embodiments of the present disclosure, the thermal efficiency of the speaker apparatus may be improved because heat dissipation may be performed more efficiently within a single main body.

According to various embodiments of the present disclosure, it is possible to eliminate standing waves that may occur in the flow path provided in one main body.

According to various embodiments of the present disclosure, a separate sound-absorbing material may not be required to eliminate standing waves in one main body, thereby reducing manufacturing costs.

The effects according to the idea of the present disclosure are not limited to the effects mentioned above, and other effects not mentioned will be clearly understood by those of ordinary skill in the art to which the present invention pertains from the following description.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a perspective view illustrating a speaker apparatus according to an embodiment of the present disclosure;

FIG. 2 is a rear view illustrating the speaker apparatus according to an embodiment of the present disclosure;

FIG. 3 is a perspective view illustrating the speaker apparatus according to an embodiment of the present disclosure with a cover disassembled;

FIG. 4 is a cross-sectional view of the speaker apparatus taken along line A-A′ shown in FIG. 1;

FIG. 5 is a cross-sectional view of the speaker apparatus taken along line B-B′ shown in FIG. 1;

FIG. 6 is an enlarged view illustrating a portion of the speaker apparatus shown in FIG. 4;

FIG. 7 is a perspective view illustrating a heat sink according to an embodiment of the present disclosure;

FIG. 8 is a schematic view illustrating a physical structure of a low pass filter (LPF) according to an embodiment of the present disclosure;

FIG. 9 is a view illustrating acoustic data comparing before and after a configuration of the LPF is provided in a flow path, according to an embodiment of the present disclosure;

FIG. 10 is a view illustrating the temperature of a heat sink without heat exchange fins; and

FIG. 11 is a view illustrating the temperature of a heat sink with heat exchange fins according to an embodiment of the present disclosure.

### DETAILED DESCRIPTION

Various embodiments of the present disclosure and terms used herein are not intended to limit the technical features described in the present disclosure to specific embodiments, and should be understood to include various modifications, equivalents, or substitutes of the corresponding embodiments.

In addition, the same reference numerals or signs shown in the drawings of the disclosure indicate elements or components performing substantially the same function.

Also, the terms used herein are used to describe the embodiments and are not intended to limit and/or restrict the disclosure. The singular forms “a,” “an” and “the” are intended to include the plural forms as well, unless the context clearly indicates otherwise. In this disclosure, the terms “including”, “having”, and the like are used to specify features, figures, steps, operations, elements, components, or combinations thereof, but do not preclude the presence or addition of one or more of the features, figures, steps, operations, elements, components, or combinations thereof.

It will be understood that, although the terms “first”, “second”, “primary”, “secondary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

Further, as used in the disclosure, the terms “front”, “rear”, “top”, “bottom”, “side”, “left”, “right”, “upper”, “lower”, and the like are defined with reference to the drawings, and are not intended to limit the shape and position of any element.

Hereinafter, various embodiments according to the disclosure will be described in detail with reference to the accompanying drawings.

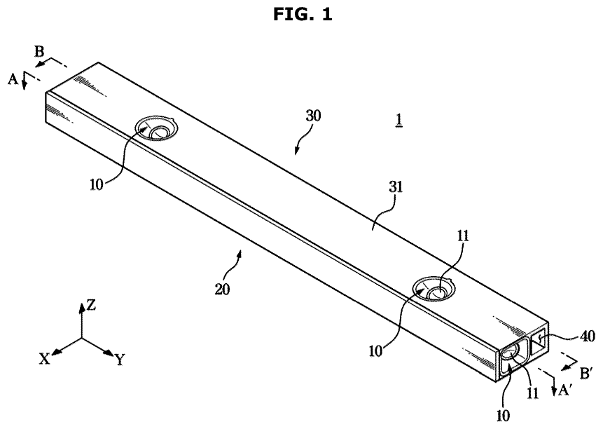

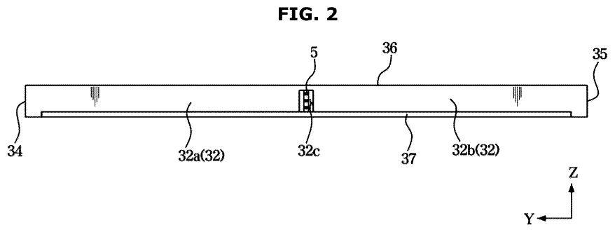

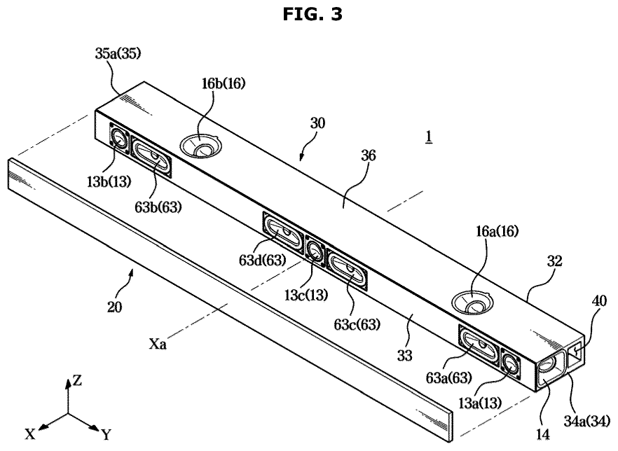

FIG. 1 is a perspective view illustrating a speaker apparatus according to an embodiment of the present disclosure. FIG. 2 is a rear view illustrating the speaker apparatus according to an embodiment of the present disclosure. FIG. 3 is a perspective view illustrating the speaker apparatus according to an embodiment of the present disclosure with a cover disassembled.

Referring to FIGS. 1 to 3, a speaker apparatus 1 may include a speaker 10, a main body 30 on which the speaker 10 is mounted, and a cover 20 arranged on a front side of the main body 30. The speaker apparatus 1 may be formed in a bar type shape.

The speaker 10 may be a device that generates sound by converting electrical signals into vibrations of a vibrating plate 11 (e.g., a diaphragm). The speaker 10 may include a magnetic circuitry and a vibration system (e.g., a vibrator).

The magnetic circuitry may be a portion to which an electrical signal is transmitted to the speaker 10 to generate sound. The magnetic circuitry may include a magnet and a pole piece disposed in the center of the magnet.

The vibration system may be portion in which sound is generated and output as vibration, and include a voice coil arranged in a gap formed between the magnet and the pole piece, a bobbin on which the voice coil is installed, and the diaphragm 11 configured to be movable by a magnetic circuit in which the magnetic circuitry is formed.

With such a structure, the speaker 10 may produce sound by converting electrical signals into vibrations of the diaphragm 11, and generating compression waves in the air through the vibrations.

A plurality of speakers 10 may be provided, and may be arranged symmetrically with respect to each other. More specifically, the speakers 10 may be arranged in planar symmetry with respect to each other based on a central axis Xa of the main body 30.

The main body 30 may have a bar-type shape extending in a first direction (e.g., Y direction). The main body 30 may be provided in a substantially cuboidal shape with the first direction (e.g., Y direction) being a longitudinal direction. The main body 30 may have a long side in the first direction (e.g., Y direction). The main body 30 may have short sides in a front-to-back direction (e.g., X direction) and a height direction (e.g., Z direction).

The main body 30 may include an outer wall 31 forming an exterior thereof, and an inner wall 50 provided inside the main body 30. The outer wall 31 may include a front wall 33 facing the cover 20 and a rear wall 32 parallel to the front wall 33 and facing the rear.

The outer wall 31 may further include a right wall 34, a left wall 35, a lower wall 37, and an upper wall 36, which are arranged between the front wall 33 and the rear wall 32, respectively. The outer wall 31 may have an opening 40 formed in each of side surfaces 34a and 35a. The openings 40 may be configured to allow air inside the main body 30 to be discharged to an outside of the main body 30.

The rear wall 32 may include a first rear wall 32a and a second rear wall 32b. The first and second rear walls 32a and 32b may be spaced apart from each other in the first direction (e.g., Y direction) to form a connection hole 32c. The first and second rear walls 32a and 32b may be symmetrically shaped with respect to each other centering on the connection hole 32c.

The speaker apparatus 1 may generate sound by receiving an electrical signal from other external home appliances by physically connecting a wire to the connection hole 32c. However, the speaker apparatus 1 is not limited to such a method, and may be wirelessly connected to other home appliances through a wireless communication method to transmit and receive signals.

The speaker apparatus 1 may include the plurality of speakers 10. The speakers 10 may be classified into a cone speaker, a dome speaker, a plate speaker, a ribbon speaker, a horn speaker, and a micro-speaker depending on the shape of the diaphragm 11.

The cone speaker may be a speaker in which the diaphragm 11 is shaped like a cone, and the frequency characteristics are generally flat and the sound in the low-frequency range may be spread in all directions of 360 degrees.

The dome speaker may be a speaker in which the diaphragm 11 is shaped like a dome, and may be characterized in that the reproduction range is wide and spread evenly.

The plate speaker may refer to a speaker in which the diaphragm 11 is shaped like a flat without curvature, so that there is no time difference in the arrival of the sound generated from a plurality of speakers. The generated sound may have the characteristics of a spherical wave and a plane wave rather than a pure spherical wave, which may be characterized in that the sound may be sent far away.

The ribbon speaker may be a speaker having a ribbon-like shape, and may have the characteristic that the driving force for moving the diaphragm 11 is not generated from the voice coil, but is directly generated from the diaphragm 11 itself.

The horn speaker may be a speaker having a horn-like shape, and may have a characteristic of concentrating sound in one direction.

A micro-speaker may be a speaker having a size (diameter) of 40 to 50 mm or less, and may be used mainly for small-sized products.

The plurality of speakers 10 may be used as flat panel speakers, but are not limited thereto.

The speaker 10 may include a pair of upper speakers 16 mounted on the upper wall 36 of the main body 30. The upper speakers 16 may be arranged one on one side and one on the other side of the upper wall 36 with respect to the central axis Xa.

The upper speakers 16 may include a first upper speaker 16a mounted on a right side of the upper wall 36 and a second upper speaker 16b mounted on a left side of the upper wall 36. The first upper speaker 16a and the second upper speaker 16b may each be arranged such that the generated sound is from the upper left and right sides of the speaker apparatus 1.

The speaker 10 may include a first side speaker 14 mounted on the right wall 34 of the main body 30 and a second side speaker 15 mounted on the left wall 35 of the main body 30.

The first side speaker 14 and the second side speaker 15 may each be arranged to generate sound from the right wall 34 and the left wall 35 of the speaker apparatus 1 in a left-and-right direction of the speaker apparatus 1.

The first side speaker 14 and the second side speaker 15 may be arranged to be inclined to face forward. The first side speaker 14 may be inclined toward the front as it faces to the right, and the second side speaker 15 may be inclined toward the front as it faces to the left.

The speaker 10 may include a plurality of front speakers 13 mounted on the front wall 33 of the main body 30. Three front speakers 13 may be provided. The front speakers 13 may include a first front speaker 13a arranged on the right side of the front wall 33, a second front speaker 13b arranged on the left side of the front wall 33, and a third front speaker 13c arranged on the central axis Xa.

The first front speaker 13a may generate sound toward the right side of the front (e.g., X direction) of the main body 30, and the second front speaker 13b may generate sound toward the left side of the front (e.g., −X direction) of the main body 30. The third front speaker 13c may be arranged on the central axis Xa of the main body 30 to generate sound toward the front (e.g., X direction). However, the shape, location, and number of the speakers 10 are not limited thereto.

A plurality of woofers 63 may be mounted on the front wall 33 of the main body 30. The woofers may be configured to produce bass sounds below 3,000 Hz in the audible frequency range. The plurality of woofers 63 may be mounted on the main body 30 to generate sounds with a range of different frequencies to improve consumer satisfaction.

The plurality of woofers 63 may include a first woofer 63a arranged on the right side of the central axis Xa of the main body 30 and a second woofer 63b arranged on the left side of the central axis Xa of the main body 30. The first woofer 63a may be arranged adjacent to the first front speaker 13a. The second woofer 63b may be arranged adjacent to the second front speaker 13b.

The plurality of woofers 63 may include a third woofer 63c and a fourth woofer 63d provided as a pair adjacent to the third front speaker 13c. However, the location and number of the woofers 63 are not limited thereto.

A cover 20 may be attached to a front surface of the main body 30. The cover 20 may be coupled to the front wall 33 to protect the front speakers 13 and the plurality of woofers 63 arranged on the front wall 33 of the main body 30. The cover 20 may be provided in the shape of a grille. With such a shape, the cover 20 may prevent the front speakers 13 and the front woofers 63 from being pressed by any sharp members, and may also have an aesthetic effect.

However, the arrangement and shape of the cover 20 is not limited thereto, and may be configured to cover the upper wall 36, the right wall 34, and the left wall 35 of the main body 30.

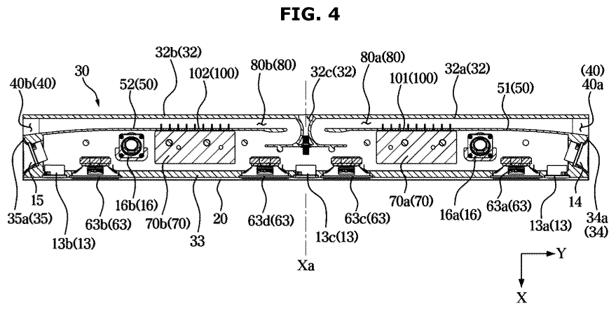

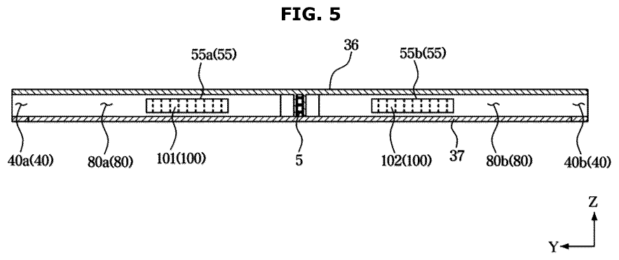

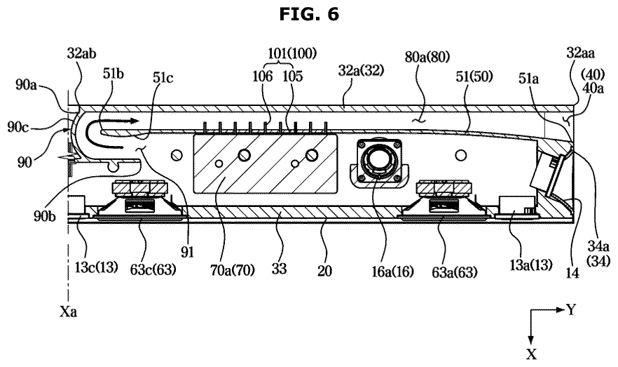

FIG. 4 is a cross-sectional view of the speaker apparatus taken along line A-A′ shown in FIG. 1. FIG. 5 is a cross-sectional view of the speaker apparatus taken along line B-B′ shown in FIG. 1. FIG. 6 is an enlarged view illustrating a portion of the speaker apparatus shown in FIG. 4.

Referring to FIGS. 4 to 6, the configuration of the speaker apparatus 1 may be arranged in planar symmetry about the central axis Xa. The speaker apparatus 1 may include an electronic component 70 disposed inside the main body 30. The electronic component 70 may include a printed board assembly (PBA) or the like that is connected to the plurality of speakers 10. The electronic components 70 may include a first electronic component 70a located on one side (e.g., Y direction) with respect to the central axis Xa of the main body 30 and a second electronic component 70b located on the other side (e.g., −Y direction) with respect to the central axis Xa of the main body 30.

The electronic components 70 may include a printed circuit board (PCB). The PCB may be a board, such as a substrate, in which conductive circuitry is formed on the surface or inside of an insulating substrate to connect components, and may require heat dissipation. Due to such a structure, the main body 30 may require a structure for an internal air inside the main body 30 to be discharged to an outside of the main body 30 while carrying heat from the electronic components 70.

The speaker apparatus 1 may have the pair of openings 40 arranged on opposite side surfaces 34a and 35a through which the air inside the main body 30 may be discharged to the outside of the main body 30. The pair of openings 40 may include a first opening 40a arranged in the right side surface 34a and a second opening 40b arranged in the left side surface 35a.

The speaker apparatus 1 may include the inner wall 50. The inner wall 50 may be formed to be spaced apart from the first rear wall 32a and the second rear wall 32b so as to form a flow path 80 communicating with each of the pair of openings 40. The inner wall 50 may include a first inner wall 51 forming a first flow path 80a and a second inner wall 52 forming a second flow path 80b.

The main body 30 may include the first flow path 80a arranged between the first inner wall 51 and the first rear wall 32a and extending in the first direction (e.g., Y direction). The main body 30 may include the second flow path 80b arranged between the second inner wall 52 and the second rear wall 32b and extending in a direction opposite to the first flow path 80a.

The speaker apparatus 1 may include a heat sink 100, a configuration that is in contact with the electronic component 70 and absorbs heat from the electronic component 70. The heat sink 100 may be attached to one surface of the electronic component 70 to absorb heat from the electronic component 70.

The heat sink 100 may include a plurality of heat exchange fins 106 protruding toward the flow path 80 and a connection plate 105 connecting the plurality of heat exchange fins 106. The plurality of heat exchange fins 106 may protrude from the connection plate 105 toward the flow path 80. The plurality of heat exchange fins 106 may protrude from the connection plate 105 toward the rear wall 32.

The heat sinks 100 may include a first heat sink 101 and a second heat sink 102, each attached to the respective electronic components 70.

The electronic component 70 may be located on a front side of the inner wall 50, and the flow path 80 may be located on a rear side of the inner wall 50. The heat sink 100 attached to the electronic component 70 may extend in the first direction (e.g., Y direction).

The heat sink 100 may be mounted to the inner wall 50 so as to extend in the first direction, which is a direction of extension of the inner wall 50. The heat sink 100 may extend in a longitudinal direction along a direction in which the inner wall 50 extends. More specifically, the connection plate 105 may extend in the longitudinal direction along the direction in which the inner wall 50 extends.

The heat sink 100 may be configured to receive heat from the electronic component 70 and dissipate heat to the outside of the electronic component 70, and may be arranged on the inner wall 50 to increase the contact area with the flow path 80.

According to such a structure, the heat sink 100 may be arranged in the main body 30 and extend along the longitudinal direction of the flow path 80, so that heat exchange with the air flowing in the flow path 80 may be performed more smoothly. In other words, the heat sink 100 may include a structure mounted on the inner wall 50 such that the first direction (e.g., Y direction) is the longitudinal direction, so that heat from the electronic component 70 may be transferred more quickly, thereby lowering the temperature of the electronic component 70.

To accomplish such a structure, the heat sink 100 may be configured to penetrate the inner wall 50. The inner wall 50 may include a plate hole 55 into which the connection plate 105 is inserted to allow the connection plate 105 to contact the electronic component 70. The plate hole 55 may be formed in a substantially rectangular shape and may be formed to correspond to the connection plate 105.

The plate hole 55 may include a first plate hole 55a formed in the first inner wall 51 and a second plate hole 55b formed in the second inner wall 52.

When the speaker apparatus 1 (see FIG. 1) receives an electrical signal to cause the speaker 10 to generate sound, the air inside the main body 30 may flow into the first flow path 80a in the direction of the arrow shown in FIG. 6. The air flowing into the first flow path 80a may be discharged to the outside of the main body 30 through the first opening 40a along the first inner wall 51 and the first rear wall 32a.

The structure of the inner wall 50 and the rear wall 32 extending in the first direction (e.g., Y direction) may allow the flow path 80 to also extend in the first direction, and allow the flow path to be formed in the longest direction in the main body 30. In such a structure, since the heat sink 100 is arranged on the inner wall 50, heat from the electronic component 70 may be relatively easily dissipated into the flow path 80, and accordingly the temperature of the electronic component 70 may be lowered.

A distance between the first inner wall 51 and the first rear wall 32a increases toward the first opening 40a such that the first flow path 80a widens toward one end 51a connected to the right side surface 34a from the inside of the main body 30. Such a structure may allow the air flowing through the first flow path 80a to be more easily discharged to the outside of the main body 30 through the first opening 40a.

The first rear wall 32a may include one end 32aa connected to the right side surface 34a and the other end 32ab near the connection hole 32c. One end 32aa of the first rear wall 32a may form the first opening 40a. The other end 32ab of the first rear wall 32a may be located on the opposite side of one end 32aa of the first rear wall 32a.

The first inner wall 51 may include one end 51a forming the first opening 40a and the other end 51b facing the central axis Xa. One end 51a of the first inner wall 51 may form the first opening 40a together with one end 32aa of the first rear wall 32a. The other end 51b of the first inner wall 51 may be located on the opposite side from one end 51a of the first inner wall 51.

The main body 30 may include a guide wall 90 extending forwardly from the other end 32ab of the first rear wall 32a and forming an inlet of the first flow path 80a. The guide wall 90 may be spaced apart from the other end 51b of the first inner wall 51 so as to surround the other end 51b of the first inner wall 51. The guide wall 90 may be formed to be curved.

The guide wall 90 may include one end 90a connected to the other end 32ab of the first rear wall 32a and the other end 90b disposed inside the main body 30. The other end 90b of the guide wall 90 may be spaced apart from the first inner wall 51. The other end 90b of the guide wall 90 may be spaced apart from the first inner wall 51 to form a guide hole 91. The guide hole 91 may be positioned on a front side of the first inner wall 51 and may communicate with the first flow path 80a. The air inside the main body 30 may be discharged through the guide hole 91 into the first flow path 80a and through the first opening 40a to the outside of the main body 30.

The guide wall 90 may include a rounded portion 90c arranged between one end 90a and the other end 90b. The rounded portion 90c may allow the air flowing in through the guide hole 91 to flow into the first flow path 80a with relatively low resistance.

The first inner wall 51 may include a guide portion 51c that guides the air entering through the guide hole 91 to the flow path side located on the rear side of the first inner wall 51. The guide portion 51c may be adjacent to the other end 51b of the first inner wall 51. The guide portion 51c may be provided in a rounded shape so as to protrude toward the guide wall 90. Due to the shape of the guide portion 51c, the air flowing through the guide hole 91 may flow smoothly into the first flow path 80a located on the rear side of the first inner wall 51.

The configurations of the speaker apparatus 1 may be arranged in planar symmetry about the central axis Xa, so that a description of the left portion of the main body 30 corresponding to the right portion of the main body 30 will be omitted.

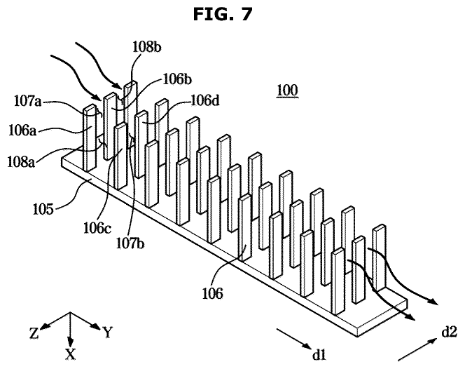

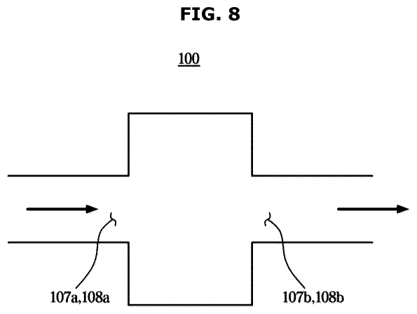

FIG. 7 is a perspective view illustrating the heat sink according to an embodiment of the present disclosure. FIG. 8 is a schematic view illustrating a physical structure of a low pass filter (LPF) according to an embodiment of the present disclosure.

Referring to FIGS. 7 and 8, the heat sink 100 may include the connection plate 105 extending in a first direction d1, and the plurality of heat exchange fins 106 protruding from the connection plate 105.

On the other hand, in a case such as one-body shaped speaker apparatus 1 (see FIG. 1) of the present disclosure, a standing wave may be formed because the flow path 80 (see FIG. 4) through which the air inside the main body 30 is discharged to the outside of the main body 30 is formed between the rear wall 32 and the inner wall 50.

A standing wave is a phenomenon that occurs when the distance between the walls is constant in relation to the wavelength of the sound as the sound is reflected back and forth between the parallel walls facing each other. In other words, when the distance between the rear wall 32 and the inner wall 50 is in a constant relationship to the wavelength of the sound, the peaks and valleys of the sound waves are strongly amplified, causing the sound to resonate, which may be one of the resonance phenomena. The resonant sound waves generated by this principle may be referred to as standing waves.

To eliminate standing waves, a separate sound-absorbing material (e.g., an acoustic sponge) may be disposed inside the main body 30. However, according to the ideas of the present disclosure, the structure of a standing wave filter may be realized without a separate sound-absorbing material. The arrangement structure of the plurality of heat exchange fins 106 may function as such a standing wave filter.

The plurality of heat exchange fins 106 may be arranged to be spaced apart from each other in a first direction d1 and a second direction d2. The first direction d1 may be a flow direction of the air flowing in the flow path 80 (see FIG. 4). The second direction d2 may be a direction perpendicular to the first direction d1. The first direction d1 and the second direction d2 may be the directions of extension of a long side and a short side of the connection plate 105, respectively.

The plurality of heat exchange fins 106 may include a first heat exchange fin 106a, a second heat exchange fin 106b, a third heat exchange fin 106c, and a fourth heat exchange fin 106d. The second heat exchange fin 106b may be spaced apart from the first heat exchange fin 106a in the second direction d2. The third heat exchange fin 106c may be spaced apart from the first heat exchange fin 106a in the first direction d1. The fourth heat exchange fin 106d may be spaced apart from the second heat exchange fin 106b in the first direction d1, and spaced apart from the third heat exchange fin 106c in the second direction d2.

With respect to the flow direction of the air, the air may pass between the first heat exchange fin 106a and the second heat exchange fin 106b, and then pass between the third heat exchange fin 106c and the fourth heat exchange fin 106d.

An inlet 107a may be formed between the first heat exchange fin 106a and the second heat exchange fin 106b, and an outlet 107b may be formed between the third heat exchange fin 106c and the fourth heat exchange fin 106d. The air flowing in the flow path 80 may flow from the inlet 107a to the outlet 107b. The outlet 107b may be arranged in the first direction d1 with respect to the inlet 107a.

The first heat exchange fin 106a to the fourth heat exchange fin 106d may be provided in a plurality, and thus the inlet 107a and the outlet 107b may also be provided in a plurality.

In addition, an inlet 108a may be formed between the first heat exchange fin 106a and the third heat exchange fin 106c, and an outlet 108b may be formed between the second heat exchange fin 106b and the fourth heat exchange fin 106d. As such, the inlets 107a and 108a and the outlets 107b and 108b may be opposed holes, without limiting their location.

Waves in the air flowing within the flow path 80 may be reflected by the inner wall 50 or the rear wall 32 and return to pass through the inlets 107a and 108a and pass through the outlets 107b and 108b, and frequencies having specific bands may continuously create reflections or interferences on the wall or the heat exchange fins 106. Such a structure may prevent peaks or dips in acoustic data caused by standing waves. In other words, according to the ideas of the present disclosure, as shown in FIG. 8, the structure of the LPF may be realized using the arrangement of the plurality of heat exchange fins 106.

Embodiments of the present disclosure are not limited to the structure in which the plurality of heat exchange fins 106 shown in FIG. 7 are spaced apart from each other at regular intervals, but it is sufficient to realize a standing wave filter structure using various arrangements of the plurality of heat exchange fins 106.

As a result, in the present disclosure, a separate sound-absorbing material may not be required, so that the costs may be reduced. Furthermore, the arrangement of the plurality of heat exchange fins 106 may be freely made to implement the structure of a standing wave filter while relatively not obstructing the flow of air flowing in the flow path 80.

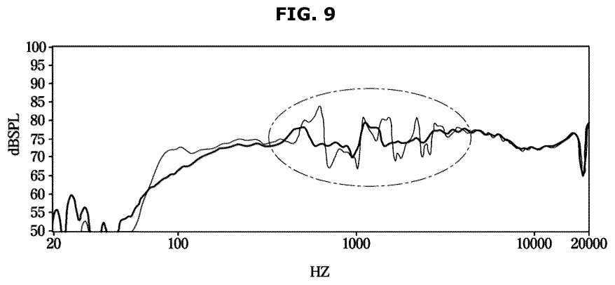

FIG. 9 is a view illustrating acoustic data comparing before and after the configuration of the LPF is provided in the flow path according to an embodiment of the present disclosure.

Referring to FIG. 9, FIG. 9 shows acoustic data comparing a structure in which the structure of an LPF is implemented using a plurality of silicon rubbers in the flow path and a structure in which it is not implemented.

In FIG. 9, the dark line is acoustic data of the structure in which the structure of the LPF is implemented, and the light line is acoustic data of the structure in which the structure of the LPF is not implemented. The horizontal direction is in units of Hz, and the vertical direction is in units of dBSPL. Hz is a unit of frequency, and dBSPL may be a value obtained by dividing the sound pressure by the reference sound pressure, taking the common logarithm, and multiplying it by 20. Sound pressure may be the pressure generated by sound waves passing through a medium. The reference sound pressure may refer to the minimum audible value for the sound of a plane wave of 1 kHz.

In the case of implementing the structure of the LPF, it can be seen that the peak or dip in the value for sound pressure is eliminated at a certain hertz (Hz), for example, around 1000 hertz, compared to the structure in which the structure of the LPF is not implemented.

Although FIG. 9 shows data in which the structure of a standing wave filter is implemented with the structure of the silicone rubber, it can be seen that the structure of the standing wave filter may also be implemented with the structure of the plurality of heat exchange fins 106, and a peak or dip in the sound pressure of a characteristic frequency may be eliminated.

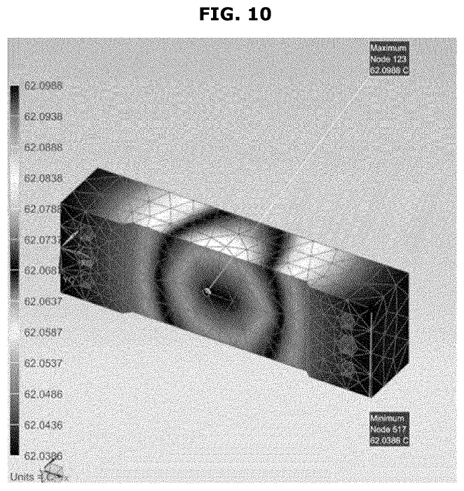

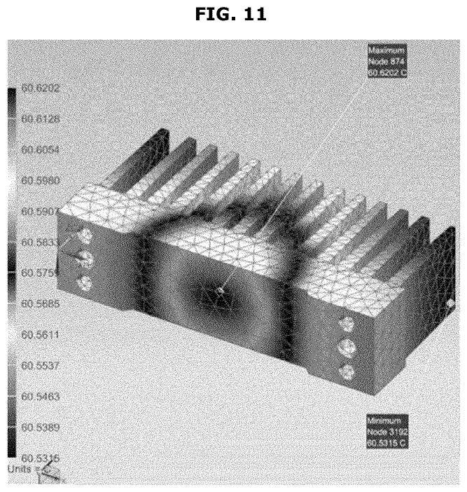

FIG. 10 is a view illustrating the temperature of the heat sink without heat exchange fins. FIG. 11 is a view illustrating the temperature of the heat sink with heat exchange fins according to an embodiment of the present disclosure.

As can be seen in FIG. 10, for the heat sink 100 without the heat exchange fins 106 (see FIG. 7), the temperature of the hottest portion is 62.0988° C., and the temperature of the coldest portion is 62.0386° C.

As can be seen in FIG. 11, for the heat sink 100 with the heat exchange fins 106 (see FIG. 7), the temperature of the hottest portion is 60.6202° C., and the temperature of the coldest portion is be 60.5315° C.

Compared to FIG. 10, the heat sink 100 with the heat exchange fins 106 of FIG. 11 has the hottest portion at 60.6202° C., which is lower than 62.0988° C., and the coldest portion is also 60.5315° C., which is lower than 62.0386° C.

Such a structure may allow the heat sink 100 having the heat exchange fins 106 to dissipate more heat than a heat sink having a simple plate shape, thereby lowering the temperature. In other words, the temperature of the electronic component 70 attached to the heat sink 100 may be lowered relatively quickly.

Although FIGS. 10 to 11 compare experimental data with a simple heat sink configuration, it can be seen that the structure of the heat sink 100 according to the ideas of the present disclosure may dissipate heat from the electronic component 70 more quickly than a heat sink consisting solely of the shape of the connection plate 105.

According to the ideas of the present disclosure, by attaching the heat sink 100 to the inner wall 50, the temperature of the electronic component 70 may be lowered relatively quickly, and at the same time, the structure of the standing wave filter may be implemented.

While certain embodiments of the present disclosure has been particularly described and shown, it should be understood by those of skilled in the art that various changes in form and details may be made without departing from the spirit and scope of the present disclosure.

What is claimed is:

1. A speaker apparatus comprising:
a main body comprising an outer wall having an opening configured to discharge air inside the main body to an outside of the main body, the outer wall comprising a rear wall extending in a first direction, and an inner wall spaced apart from the rear wall and defining a flow path in communication with the opening;
a speaker on the main body;
an electronic component inside the main body; and
a heat sink in contact with the electronic component and comprising heat exchange fins protruding toward the flow path;
wherein the plurality of heat exchange fins are spaced apart from each other in the first direction parallel to a flow direction of the air and in a second direction intersecting the first direction such that the air passing through the flow path contacts the plurality of heat exchange fins.

2. The speaker apparatus of claim 1, wherein the inner wall extends in the first direction, and the heat sink is on the inner wall so as to extend in the first direction.

3. The speaker apparatus of claim 1, wherein the heat sink penetrates the inner wall.

4. The speaker apparatus of claim 3, wherein the heat sink further comprises a connection plate connected to the plurality of heat exchange fins and attached to the electronic component, and
wherein the plurality of heat exchange fins extend from the connection plate toward the rear wall.

5. The speaker apparatus of claim 4, wherein the inner wall comprises a plate hole, and the connection plate is inserted into the plate hole and contacts the electronic component.

6. The speaker apparatus of claim 1, wherein the electronic component is on a front side of the inner wall, and the flow path is at a rear side of the inner wall.

7. The speaker apparatus of claim 1, wherein the plurality of heat exchange fins comprises:
a first heat exchange fin;
a second heat exchange fin spaced apart from the first heat exchange fin in the second direction and forming an inlet through which the air passes with the first heat exchange fin;
a third heat exchange fin spaced apart from the first heat exchange fin in the first direction; and
a fourth heat exchange fin spaced apart from the second heat exchange fin in the first direction and forming an outlet through which the air passes with the third heat exchange fin.

8. The speaker apparatus of claim 1, wherein the second direction is perpendicular to the first direction.

9. The speaker apparatus of claim 1, wherein the opening is in a side surface of the outer wall of the main body.

10. The speaker apparatus of claim 1, wherein a distance between the inner wall and the rear wall increases toward the opening such that the flow path widens toward the opening.

11. The speaker apparatus of claim 1, wherein the inner wall comprises a first end forming the opening and a second end on an opposite side of the opening, and
wherein the main body further comprises a guide wall extending from the rear wall and spaced apart from the second end of the inner wall so as to surround the second end of the inner wall.

12. The speaker apparatus of claim 11, wherein the guide wall comprises: a first end connected to the rear wall, and
a second end spaced apart from the inner wall to define a guide hole through which air inside the main body flows in.

13. The speaker apparatus of claim 12, wherein the guide wall further comprises a rounded portion configured to guide the air flowing in through the guide hole to the flow path behind the inner wall.

14. The speaker apparatus of claim 12, wherein the inner wall comprises a guide portion rounded toward the guide wall and configured to guide the air flowing in through the guide hole to the flow path on the rear side of the inner wall.

15. A speaker apparatus comprises:
a main body comprising an outer wall having an opening configured to discharge air inside the main body to an outside of the main body, the outer wall comprising a rear wall extending in in a first direction, and an inner wall spaced apart from the outer wall and defining a flow path in communication with the opening;
a speaker on the main body;
an electronic component disposed on a front side of the inner wall; and
a heat sink comprising a connection plate in contact with the electronic component and inserted into the inner wall, and a plurality of heat exchange fins protruding from the connection plate toward the flow path on a rear side of the inner wall.

16. The speaker apparatus of claim 15, wherein the plurality of heat exchange fins are spaced apart from each other in the first direction parallel to a flow direction of the air and in a second direction perpendicular to the first direction such that the air passing through the flow path contacts the plurality of heat exchange fins.

17. The speaker apparatus of claim 15, wherein the plurality of heat exchange fins comprise:
a first heat exchange fin;
a second heat exchange fin spaced apart from the first heat exchange fin in the second direction and forming an inlet into which the air flows with the first heat exchange fin;
a third heat exchange fin spaced apart from the first heat exchange fin in the first direction; and
a fourth heat exchange fin spaced apart from the second heat exchange fin in the first direction and forming an outlet through which the air passes with the third heat exchange fin.

18. The speaker apparatus of claim 15, wherein the heat sink is inside the main body.

19. A speaker apparatus comprises:
a main body extending in a first direction, the main body comprising an opening configured to discharge air inside the main body to an outside of the main body;
a speaker on the main body;
an electronic component inside the main body, and
a heat sink attached to the electronic component and comprising a plurality of heat exchange fins,
wherein the main body comprises an outer wall comprising a rear wall extending in the first direction, and an inner wall defining a flow path in communication with the opening and extending spaced apart from the rear wall,
wherein the heat sink is on the inner wall such that the plurality of heat exchange fins protrudes toward the rear wall, and
wherein the plurality of heat exchange fins are spaced apart from each other in the first direction and in a second direction perpendicular to the first direction.

20. The speaker apparatus of claim 19, wherein electronic component is on a front side of the inner wall, and the flow path is at a rear side of the inner wall, and
wherein the heat sink further comprises a connection plate connecting the plurality of heat exchange fins and penetrating the inner wall.
